(19) United States
(12) Patent Application Publication
(10) Pub. No.: US 2003/0232523 A1
(43) Pub. Date: Dec. 18, 2003

(54) Electrical connector having reliable soldering configuration

(76) Inventor: Shi-Jie Tan, Kunshan (CN)

Correspondence Address: WEI TE CHUNG, FOXCONN INTERNATIONAL, INC., 1650 MEMOREX DRIVE, SANTA CLARA, CA, 95050, US

(21) Appl. No.: 10/299,198

(22) Filed: Nov. 18, 2002

(30) Foreign Application Priority Data
Jun. 13, 2002 (TW) 91208809

(51) Int. Cl. H01R 12/00; H05K 1/00

(52) U.S. Cl. 439/83

(57) ABSTRACT

An electrical connector (1) for electrically connecting a central processing unit (CPU) with a printed circuit board (PCB) (5) includes an insulative base (2), a cover (3), and a cam actuator (4) for actuating the cover to slide along the base. The base includes a thick first portion (21), and a thin second portion (22) defining a plurality of receiving holes (223) receiving corresponding electrical terminals (224) therein. Each terminal has a solder ball (222) fused on one end thereof. The first portion has a mounting surface (212), and defines a recess (211) at a middle of the mounting surface to provide an additional path for heating airflow to reach the solder balls when the connector is soldered to the PCB. This helps ensure that every solder ball is adequately and uniformly heated, so that all the solder balls are accurately fused with the PCB at one time.

### BACKGROUND OF THE INVENTION

1. Field of the Invention

The present invention relates to an electrical connector for electrically connecting an electronic package such as a central processing unit (CPU) with a circuit substrate such as a printed circuit board (PCB), and particularly to an electrical connector with solder balls for soldering to the PCB.

2. Description of Related Art

Ball grid array (BGA) sockets are widely used in personal computer (PC) systems to electrically connect CPUs with PCBs. A BGA socket comprises a plurality of terminals, with each terminal having a solder ball attached thereon.

A conventional soldering procedure for fixing the socket on the PCB comprises the following steps. Firstly, the socket is positioned on the PCB. Secondly, the socket together with the PCB is put into an infrared (IR) oven. Thirdly, the solder balls on the terminals of the socket are heated, melted and fixed on the PCB. The socket is thereby fixed on the PCB via the solder balls. This conventional procedure is disclosed in “BGA sockets: a dendritic solution” (P460-466, 1996 IEEE 46th electronic Components & Technology Conference).

Referring to FIGS. 5, 6 and 7, a conventional electrical connector 9 for electrically connecting a CPU (not shown) with a PCB 8 comprises an insulative base 91, a rectangular cover 92 slidably engaged on the base 91 and adapted to have the CPU seated thereon, and a cam actuator 93 for actuating the cover 92 to slide along the base 91 to electrically connect or disconnect the CPU with the PCB. The base 91 comprises a thick first portion 94 defining a mounting surface 941 for mounting on the PCB 8, and a thin second portion 95 defining a plurality of receiving holes for receiving corresponding electrical terminals therein. Each terminal comprises a solder ball 954 fused on one end thereof that faces toward the PCB 8. The cover 92 has a pair of protrusions 96 formed on two bottom corner portions thereof respectively. Bottom extremities of the first portion 94 and the protrusions 96 are at a same level, such level being parallel to a bottom surface of the second portion 95. This helps ensure that the electrical connector 9 and the PCB 8 are coplanar when the solder balls 954 are soldered to the PCB 8.

When the electrical connector 9 is soldered on the PCB 8, the solder balls 954 are heated and melted. The mounting surface 941 of the first portion 94 of the base 91 in cooperation with the protrusion 96 of the cover 92 control an extent to which the melted solder balls 954 deform. This helps ensure that the electrical connector 9 and the PCB 8 are coplanar. However, the first portion 94 prevents heating airflow from reaching certain areas of the second portion 95, especially a central area of the second portion 95 close to the first portion 94. As a result, solder balls 954 located in said central area cannot be adequately and uniformly heated. As a result, the solder balls 954 cannot be accurately fused with the PCB 8 at one time. This can lead to faulty performance or even failure of the electrical connector 9.

A new electrical connector that overcomes the above-mentioned disadvantages is desired.

### SUMMARY OF THE INVENTION

Accordingly, an object of the present invention is to provide an electrical connector for electrically connecting a CPU with a PCB which can ensure that all solder joints of the connector are adequately and uniformly heated when the connector is soldered to the PCB.

To achieve the above-mentioned object, an electrical connector in accordance with a preferred embodiment of the present invention is for electrically connecting a CPU with a PCB. The connector comprises an insulative base, a rectangular cover slidably engaged on the base, and a cam actuator for actuating the cover to slide along the base. The base comprises a thick first portion for partially receiving the cam actuator therein, and a thin second portion defining a plurality of receiving holes receiving corresponding electrical terminals therein. Each terminal has a solder ball fused on one end thereof that faces toward the PCB. The first portion has a mounting surface for mounting on the PCB. A recess is defined in the first portion at a middle of the mounting surface, to provide an additional path for heating airflow to reach the solder balls when the connector is soldered to the PCB. This helps ensure that every solder ball is adequately and uniformly heated, so that all the solder balls are accurately fused with the PCB at one time, thereby providing reliable electrical connection of the terminals to the PCB.

Other objects, advantages and novel features of the invention will become more apparent from the following detailed description when taken in conjunction with the accompanying drawings, in which:

### BRIEF DESCRIPTION OF THE DRAWINGS

FIG. 1 is a simplified isometric view of an electrical connector in accordance with the present invention, viewed from a bottom aspect;

FIG. 2 is an isometric view of the electrical connector of FIG. 1 mounted on a PCB, viewed from a top aspect;

FIG. 3 is a left side plan view of FIG. 2.

FIG. 4 is a bottom plan view of part of the electrical connector of FIG. 1, showing heating airflow paths in and around the electrical connector;

FIG. 5 is a simplified isometric view of a conventional electrical connector, viewed from a bottom aspect;

FIG. 6 is an isometric view of the electrical connector of FIG. 5 mounted on a PCB, viewed from a top aspect; and

FIG. 7 is a bottom plan view of part of the electrical connector of FIG. 5, showing heating airflow paths around the electrical connector.

### DETAILED DESCRIPTION OF PREFERRED EMBODIMENT OF THE INVENTION

Reference will now be made to the drawings to describe the present invention in detail.

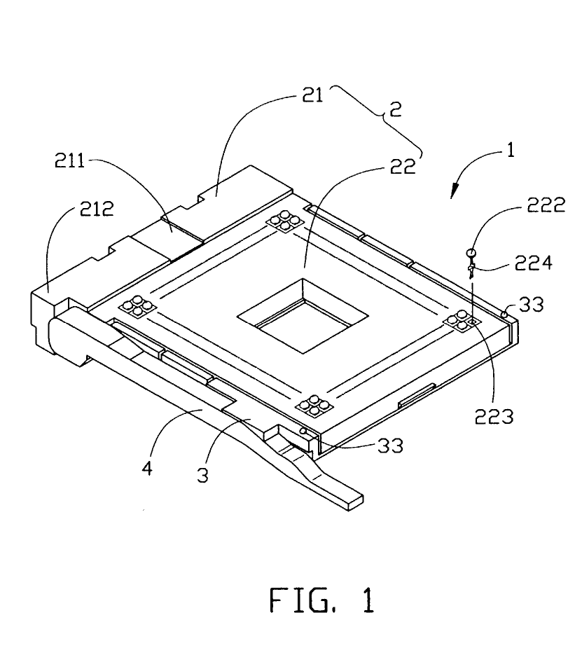

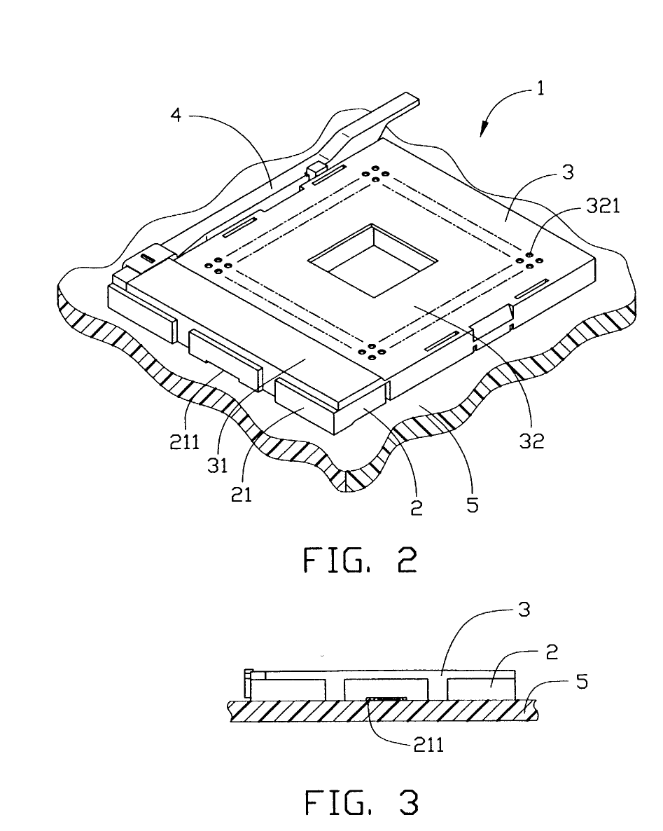

Referring to FIGS. 1 and 2, an electrical connector 1 in accordance with a preferred embodiment of the present invention comprises an insulative base 2, a rectangular cover 3 slidably engaged on the base 2, and a cam actuator 4 for actuating the cover 3 to slide along the base 2. The base 2 includes a thick first portion 21 for partially receiving the cam actuator 4 therein, and a thin second portion 22 defining a plurality of receiving holes 223 for receiving a plurality of corresponding electrical terminals 224 therein. Each terminal 224 comprises a solder ball 222 fused on one end thereof that faces toward a printed circuit board (PCB) 5. The first portion 21 has a mounting surface 212 for mounting on the PCB 5. A recess 211 is defined in the first portion 21 at a middle of the mounting surface 212.

Referring also to FIG. 2, the cover 3 comprises a holding portion 31 and a receiving portion 32. The holding portion 31 receives the cam actuator 4 and the first portion 21 of the base 2. The receiving portion 32 corresponds to the second portion 22 of the base 2, and receives a central processing unit (CPU, not shown) thereon. The receiving portion 32 defines a plurality of through holes 321 therein for receiving lead pins of the CPU, so that the lead pins can further extend into the receiving holes 223 of the base 2 and engage with the terminals 224 therein. The cover 3 has a pair of protrusions 33 respectively formed on two bottom corner portions thereof that are distal from the first portion 21 of the base 2. Bottom extremities of the first portion 21 and the protrusions 33 are at a same level, such level being parallel to a bottom surface of the second portion 22 of the base 2. This helps ensure that the electrical connector 1 and the PCB 5 are coplanar when the solder balls 222 are soldered to the PCB 5.

Referring also to FIG. 3, when the electrical connector 1 is soldered on the PCB 5, the solder balls 222 are heated and melted. The mounting surface 212 of the first portion 21 of the base 2 in cooperation with the protrusions 33 of the cover 3 control an extent to which the melted solder balls 222 deform. This helps ensure that the electrical connector 1 and the PCB 5 are coplanar.

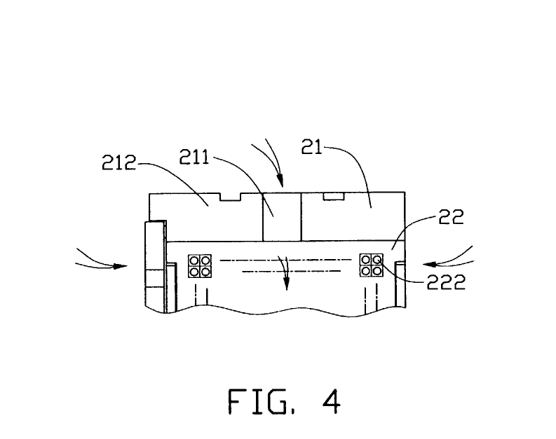

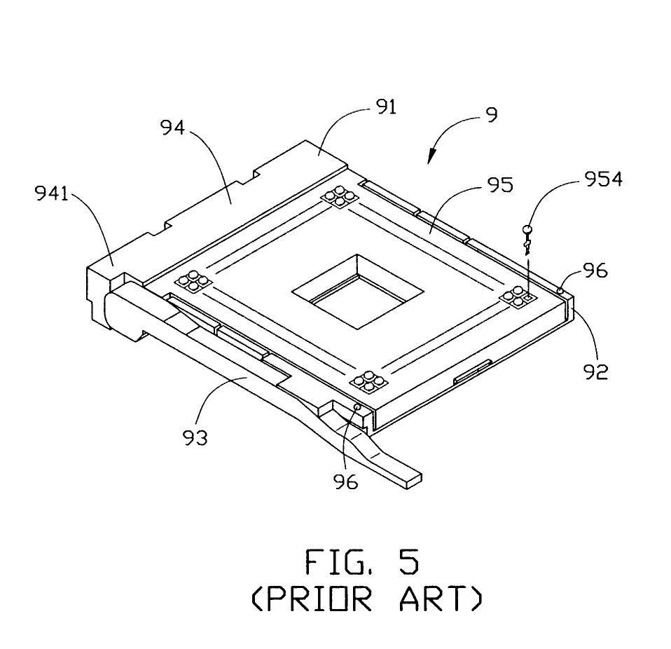

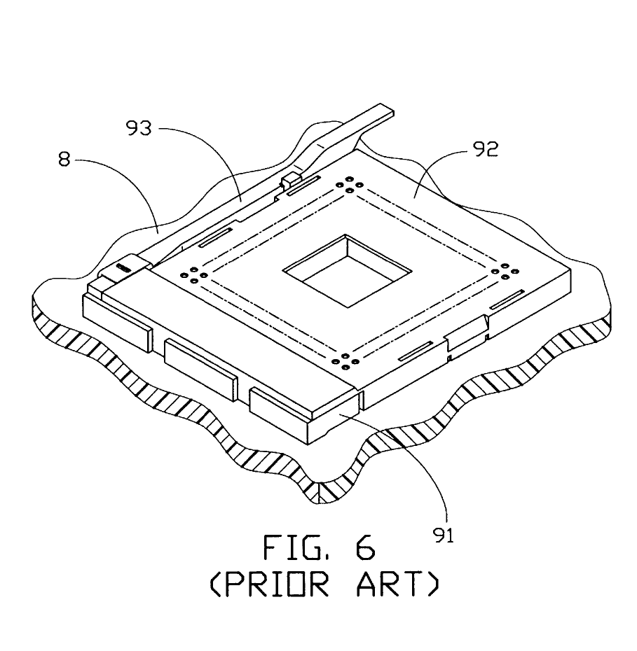

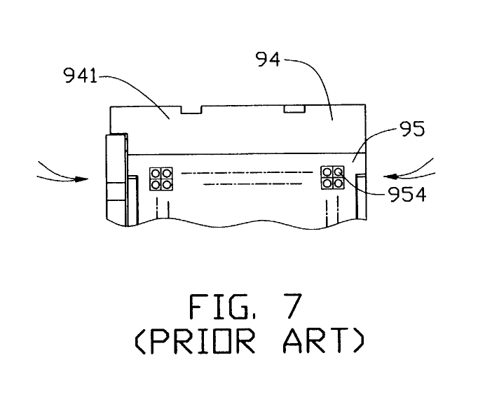

Referring to FIG. 4, the recess 211 of the first portion 21 provides an additional path for heating airflow to reach the solder balls 222. This helps ensure that every solder ball 222 is adequately and uniformly heated, so that all the solder balls 222 are accurately fused with the PCB 5 at one time, thereby providing reliable electrical connection of the terminals 224 to the PCB 5.

While a preferred embodiment in accordance with the present invention has been shown and described, equivalent modifications and changes known to persons skilled in the art according to the spirit of the present invention are considered within the scope of the present invention as defined in the appended claims.

What is claimed is:

1. An electrical connector for electrically connecting an electronic package to a circuit substrate, the electrical connector comprising:
an insulative base comprising a first portion having a mounting surface for mounting on the circuit substrate, and a second portion having a plurality of receiving holes receiving corresponding electrical terminals therein, each of the terminals having a heat-fusible element fused on one end thereof nearest the circuit substrate; and
a cover slidably engaged on the base;
wherein the first portion defines at least one recess at the mounting surface for facilitating heating airflow to reach the heat-fusible elements.

2. The electrical connector as claimed in claim 1, wherein a cam actuator is received in the first portion of the base for actuating the cover to slide along the base.

3. The electrical connector as claimed in claim 1, wherein each of the heat-fusible elements comprises a solder ball.

4. The electrical connector as claimed in claim 1, wherein the first portion is thicker than the second portion.

5. The electrical connector as claimed in claim 1, wherein a pair of protrusions is provided on a bottom of the cover.

6. The electrical connector as claimed in claim 5, wherein the first portion and the protrusions are at a same level, such level being parallel to a bottom surface of the second portion.

7. An electrical connector for electrically connecting an electronic package to a circuit substrate, the electrical connector comprising:
a base defining a plurality of receiving holes therethrough;
a plurality of terminals received in the receiving holes respectively, each of the terminals having at least one heat-fusible element exposed out from a main surface of the base;
at least one supporting portion provided at least one side of the base; and
a cover slidably engaged on the base;
wherein at least one recess is defined in the at least one supporting portion for facilitating heating airflow to reach the heat-fusible elements.

8. The electrical connector as claimed in claim 7, wherein each of the heat-fusible elements comprises a solder ball.

9. The electrical connector as claimed in claim 7, wherein the at least one support portion is thicker than the base.

10. An electrical connector assembly for use with an electronic package, comprising:
a printed circuit board;
an insulative base seated upon the printed circuit board and including a main body with a plurality of passageways extending therethrough and an actuation section located rearwardly of the main body, where a cam is located, said actuation section defining a mounting face very close to the printed circuit board;
a plurality of terminals respectively disposed in the corresponding passageways, said terminals including solder balls solderably mounted and supported on the printed circuit board, respectively, and commonly defining a solder area; and
at least one recess formed in the mounting face to allow hot air to forwardly invade the solder area, via said recess, from a rear side of the base during a reflow process for solderably mounting the base to the printed circuit board.

11. The assembly as claimed in claim 10, wherein the main body defines a bottom face from which the solder balls extend, and said bottom face is spaced away from the printed circuit board farther than the mounting face.

12. The assembly as claimed in claim 11, wherein said mounting face functions as a standoff to supportably mount the base on the printed circuit board after said reflow process.

13. The assembly as claimed in claim 10, further including a cover slidably mounted on the base.
